(19) United States
(12) Patent Application Publication
(10) Pub. No.: US 2023/0080873 A1
(43) Pub. Date: Mar. 16, 2023

(54) An Industrial Process Model Generation System

(71) Applicant: ABB Schweiz AG, Baden (CH)

(72) Inventors: Dennis Janka, Heidelberg (DE); Benjamin Kloepper, Mannheim (DE); Moncef Chioua, Montreal (CA); Pablo Rodriguez, Ilvesheim (DE); Ioannis Lymperopoulos, Dietikon (CH); Marcel Dix, Mannheim (DE)

(73) Assignee: ABB Schweiz AG, Baden (CH)

(21) Appl. No.: 17/993,443

(22) Filed: Nov. 23, 2022

Related U.S. Application Data
(63) Continuation of application No. PCT/EP2021/060802, filed on Apr. 26, 2021.

(30) Foreign Application Priority Data
May 29, 2020 (EP) 20177360.3

(51) Int. Cl. G06F 30/27

(52) U.S. Cl. CPC G06F 30/27

(57) ABSTRACT

A model generation system includes input and output units. The input unit receives a plurality of input value trajectories comprising operational input value trajectories and simulation input value trajectories relating to an industrial process. The processing unit implements a simulator of the industrial process and generates behavioral data for at least some of the plurality of input value trajectories. The processing unit further implements a machine learning algorithm that models the industrial process, and trains the machine learning algorithm.

### CROSS-REFERENCE TO RELATED APPLICATIONS

This patent application claims priority to International Patent Application No. PCT/EP2021/060802, filed on Apr. 26, 2021, which claims priority to European Patent Application No. 20177360.3, filed on May 29, 2020, each of which is incorporated herein in its entirety by reference.

### FIELD OF THE DISCLOSURE

The present disclosure relates to an industrial process model generation system, an industrial process model selection and generation system, an industrial process model generation method, and an industrial process model selection and generation method.

### BACKGROUND OF THE INVENTION

Industrial application of machine learning usually suffers from the availability of sufficient (labeled) training data for the training of machine learning models. High fidelity simulators can be used to generate additional data to improve the quality of such machine learning models. However, running high fidelity simulations is time-consuming and computationally expensive. Blind generation of data is very expensive and does not have a guaranteed impact on the performance of the machine learning algorithm.

### BRIEF SUMMARY OF THE INVENTION

It would be advantageous to have an improved technique to generate models for industrial processes. In one general aspect, the present disclosure is directed to systems and methods that address the shortcomings of the prior art.

In a first aspect, there is provided an industrial process model generation system, comprising:

an input unit; and

a processing unit.

The input unit is configured to receive a plurality of input value trajectories comprising operational input value trajectories and simulation input value trajectories relating to an industrial process. The processing unit is configured to implement a simulator of the industrial process. The processing unit is configured to generate a plurality of industrial process behavioral data. Industrial process behavioral data is generated for at least some of the plurality of input value trajectories, and the generation of the industrial process behavioral data for the at least some of the plurality of input value trajectories comprises utilization of the simulator. The processing unit is configured to implement a machine learning algorithm that models the industrial process. The processing unit is configured to train the machine learning algorithm. The processing unit is configured to process a first behavioral data of the plurality of behavioral data with the machine learning algorithm to determine a first modelled result. The processing unit is configured to determine to train or not to train the machine learning algorithm using the first behavioral data, the determination comprising a comparison of the first modelled result with a performance condition. The processing unit is configured to process a second behavioral data of the plurality of behavioral data with the machine learning algorithm to determine a second modelled result. The processing unit is configured to determine to train or not to train the machine learning algorithm using the second behavioral data or to further train or not to further train the machine learning algorithm using the second behavioral data, the determination comprising a comparison of the second modelled result with the performance condition.

In an example, the input value trajectories are real input data or simulated input data.

### BRIEF DESCRIPTION OF THE SEVERAL VIEWS OF THE DRAWING(S)

Exemplary embodiments will be described in the following with reference to the following drawings.

FIG. 1 is a diagram of an overview workflow of a new process of model training and training data generation in accordance with the disclosure.

FIG. 2 is a diagram of an overview workflow of a new process of searching for a suitable model architecture—i.e., for a suitable machine learning algorithm—in accordance with the disclosure.

FIG. 3 is a diagram of a detailed workflow of a standard process of model training and training data generation in accordance with the disclosure.

FIG. 4 is a diagram of a detailed workflow of a new process of model training and training data generation in accordance with the disclosure.

FIG. 5 is a diagram of a detailed workflow of a new process of searching for a suitable model architecture in accordance with the disclosure.

### DETAILED DESCRIPTION OF THE INVENTION

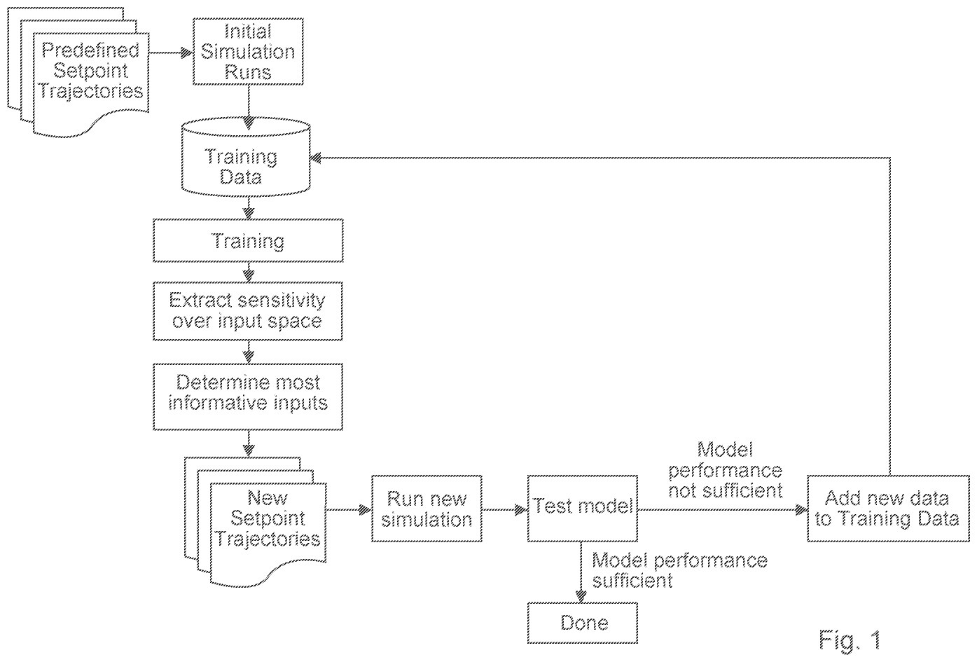

FIGS. 1-5 relate to an industrial process model generation system, an industrial process model selection and generation system, an industrial process model generation method, and an industrial process model selection and generation method.

An Industrial Process Model Generation System

An example of an industrial process model generation system comprises an input unit, and a processing unit. The input unit is configured to receive a plurality of input value trajectories comprising operational input value trajectories and simulation input value trajectories relating to an industrial process. The processing unit is configured to implement a simulator of the industrial process. The processing unit is configured to generate a plurality of industrial process behavioral data. Industrial process behavioral data is generated for the plurality of input value trajectories, and the generation of the industrial process behavioral data for the plurality of input value trajectories comprises utilization of the simulator. The processing unit is configured to implement a machine learning algorithm that models the industrial process.

The processing unit is configured to train the machine learning algorithm. The processing unit is configured to process a first behavioral data of the plurality of behavioral data with the machine learning algorithm to determine a first modelled result. The processing unit is configured to determine to train or not to train the machine learning algorithm using the first behavioral data, the determination comprising a comparison of the first modelled result with a performance condition. The processing unit is configured to process a second behavioral data of the plurality of behavioral data with the machine learning algorithm to determine a second modelled result. The processing unit is configured to determine to train or not to train the machine learning algorithm using the second behavioral data or to further train or not to further train the machine learning algorithm using the second behavioral data, the determination comprising a comparison of the second modelled result with the performance condition.

In other words, it can be determined that the machine learning algorithm can be improved by further training it with generated data, or determined that the machine learning model need not be improved with that generated data.

In an example, the performance condition comprises one or more of: a target accuracy, target false positive rates, target false negative rates.

According to an example, the plurality of input value trajectories comprises one or more of: process data; temperature data; pressure data; flow data; level data; voltage data; current data; power data; actuator data; valve data; sensor data; controller data.

According to an example, the modelled result comprises a control or monitoring output of the industrial process.

According to an example, the processing unit is configured to select the at least some of the plurality of input value trajectories.

In an example, the selection of the at least some of the plurality of input value trajectories comprises utilization of a determined sensitivity of the trained machine learning algorithm to at least a portion of the plurality of behavioral data.

According to an example, the determination to train or not to train the machine learning algorithm using the first behavioral data, comprises a determination of a sensitivity of the trained machine learning algorithm to at least a portion of the plurality of behavioral data.

According to an example, the determination to train or not to train the machine learning algorithm using the second behavioral data, comprises a determination of the sensitivity of the trained machine learning algorithm to at least a portion of the plurality of behavioral data.

According to an example, the determination to further train or not to further train the machine learning algorithm using the second behavioral data, comprises a determination of the sensitivity of the trained machine learning algorithm to at least a portion of the plurality of behavioral data.

According to an example, the determination of the sensitivity of the trained machine learning algorithm to the plurality of behavioral data comprises an analysis of a loss function of the trained machine learning algorithm with respect to at least the portion of the plurality of behavioral data.

According to an example, the processing unit is configured to determine to stop training of the machine learning algorithm, the determination comprising a determination of a sensitivity of the trained machine learning algorithm to at least a portion of the plurality of behavioral data.

An Industrial Process Model Selection and Generation System

An example of an industrial process model selection and generation system comprises an input unit, and a processing unit. The input unit is configured to receive a plurality of input value trajectories comprising operational input value trajectories and simulation input value trajectories. The processing unit is configured to implement a simulator of the industrial process. The processing unit is configured to generate a plurality of industrial process behavioral data. Industrial process behavioral data is generated for the plurality of input value trajectories, and the generation of the industrial process behavioral data for the plurality of input value trajectories comprises utilization of the simulator. The processing unit is configured to implement a plurality of machine learning algorithm that model the industrial process. The processing unit is configured to process a first behavioral data of the plurality of behavioral data with a first machine learning algorithm of the plurality of machine learning algorithms to determine a first machine learning algorithm first modelled result. The processing unit is configured to determine to train the first machine learning algorithm using the first behavioral data or implement a second machine learning algorithm of the plurality of machine learning algorithms, the determination comprising a comparison of the first machine learning algorithm first modelled result with a performance condition.

In this way, the best machine learning algorithm to be used for process monitoring can be selected and trained.

In an example, the performance condition comprises one or more of: a target accuracy, target false positive rates, target false negative rates.

According to an example, the processing unit is configured to process a second behavioral data of the plurality of behavioral data with the first machine learning algorithm to determine a first machine learning algorithm second modelled result. The processing unit is configured to determine to train the first machine learning algorithm using the second behavioral data or implement the second machine learning algorithm, the determination comprising a comparison of the first machine learning algorithm second modelled result with the performance condition.

According to an example, the processing unit is configured to process the first behavioral data with the second machine learning algorithm to determine a second machine learning algorithm first modelled result. The processing unit is configured to determine to train the second machine learning algorithm using the first behavioral data or implement a third machine learning algorithm of the plurality of machine learning algorithms, the determination comprising a comparison of the second machine learning algorithm first modelled result with the performance condition.

According to an example, the processing unit is configured to select the at least some of the plurality of input value trajectories.

In an example, the selection of the at least some of the plurality of input value trajectories comprises utilization of a determined sensitivity of the trained machine learning algorithm to at least a portion of the plurality of behavioral data.

According to an example, the determination to train the existing machine learning algorithm using behavioral data or implement a new machine learning algorithm, comprises a determination of a sensitivity of the existing trained machine learning algorithm to at least a portion of the plurality of behavioral data.

According to an example, the processing unit is configured to determine to stop training of the existing machine learning algorithm, the determination comprising a determination of the sensitivity of the trained machine learning algorithm to at least a portion of the plurality of behavioral data.

According to an example, the determination of the sensitivity of the trained machine learning algorithm to at least the portion of the plurality of behavioral data comprises an analysis of a loss function of the trained machine learning algorithm with respect to at least the portion of the plurality of behavioral data.

According to an example, the first machine learning algorithm is a simplest machine learning algorithm of the plurality of machine learning algorithms.

According to an example, the second machine learning algorithm is a second moat simplest machine learning algorithm of the plurality of machine learning algorithms.

According to an example, the third machine learning algorithm is a third most simplest machine learning algorithm of the plurality of machine learning algorithms.

An Industrial Process Model Generation Method

An example of an industrial process model generation method comprises:
receiving a plurality of input value trajectories comprising operational input value trajectories and simulation input value trajectories relating to an industrial process;
implementing by a processing unit a simulator of the industrial process;
generating by the processing unit a plurality of industrial process behavioral data, wherein the industrial process behavioral data is generated for the plurality of input value trajectories, and wherein the generation of the industrial process behavioral data for the plurality of input value trajectories comprises utilization of the simulator;
implementing by the processing unit a machine learning algorithm that models the industrial process, wherein the processing unit is configured to train the machine learning algorithm;
processing by the processing unit a first behavioral data of the plurality of behavioral data with the machine learning algorithm to determine a first modelled result;
determining by the processing unit to train or not to train the machine learning algorithm using the first behavioral data, the determination comprising a comparison of the first modelled result with a performance condition;
processing by the processing unit a second behavioral data of the plurality of behavioral data with the machine learning algorithm to determine a second modelled result; and
determining by the processing unit to train or not to train the machine learning algorithm using the second behavioral data or to further train or not to further train the machine learning algorithm using the second behavioral data, the determination comprising a comparison of the second modelled result with the performance condition.

In an example, the determining to train or not to train the machine learning algorithm using the first behavioral data, comprises determining a sensitivity of the trained machine learning algorithm to at least a portion of the plurality of behavioral data.

In an example, the determining to train or not to train the machine learning algorithm using the second behavioral data, comprises determining the sensitivity of the trained machine learning algorithm to at least a portion of the plurality of behavioral data.

In an example, the determining to further train or not to further train the machine learning algorithm using the second behavioral data, comprises determining the sensitivity of the trained machine learning algorithm to at least a portion of the plurality of behavioral data.

In an example, the determining the sensitivity of the trained machine learning algorithm to the plurality of behavioral data comprises analyzing a loss function of the trained machine learning algorithm with respect to at least the portion of the plurality of behavioral data.

In an example, method comprises determining by the processing unit to stop training the machine learning algorithm, the determining comprising determining a sensitivity of the trained machine learning algorithm to at least a portion of the plurality of behavioral data.

In an example, the method comprises selecting by the processing unit the at least some of the plurality of input value trajectories.

In an example, the selecting of the at least some of the plurality of input value trajectories comprises utilizing a determined sensitivity of the trained machine learning algorithm to at least a portion of the plurality of behavioral data.

An Industrial Process Model Selection and Generation Method

An example of an industrial process model selection and generation method comprises:
receiving a plurality of input value trajectories comprising operational input value trajectories and simulation input value trajectories relating to an industrial process;
implementing by a processing unit a simulator of the industrial process;
generating by the processing unit a plurality of industrial process behavioral data, wherein the industrial process behavioral data is generated for the plurality of input value trajectories, and wherein the generation of the industrial process behavioral data for the plurality of input value trajectories comprises utilization of the simulator;
implementing by the processing unit a first machine learning algorithm of a plurality of machine learning algorithms that model the industrial process;
processing by the processing unit a first behavioral data of the plurality of behavioral data with the first machine learning algorithm of the plurality of machine learning algorithms to determine a first machine learning algorithm first modelled result; and
determining by the processing unit to train the first machine learning algorithm using the first behavioral data or implement a second machine learning algorithm of the plurality of machine learning algorithms, the determination comprising a comparison of the first machine learning algorithm first modelled result with a performance condition.

In an example, the method comprises processing by the processing unit a second behavioral data of the plurality of behavioral data with the first machine learning algorithm to determine a first machine learning algorithm second modelled result; and determining by the processing unit to train the first machine learning algorithm using the second behavioral data or implement the second machine learning algorithm, the determination comprising a comparison of the first machine learning algorithm second modelled result with the performance condition.

In an example, method comprises processing with the processing unit the first behavioral data with the second machine learning algorithm to determine a second machine learning algorithm first modelled result; and determining by the processing unit to train the second machine learning algorithm using the first behavioral data or implement a third machine learning algorithm of the plurality of machine learning algorithms, the determination comprising a comparison of the second machine learning algorithm first modelled result with the performance condition.

In an example, the method comprises selecting by the processing unit the at least some of the plurality of input value trajectories.

In an example, the selecting of the at least some of the plurality of input value trajectories comprises utilizing a determined sensitivity of the trained machine learning algorithm to at least a portion of the plurality of behavioral data.

In an example, determining to train the existing machine learning algorithm using behavioral data or implement a new machine learning algorithm, comprises a determination of a sensitivity of the existing trained machine learning algorithm to at least a portion of the plurality of behavioral data.

In an example, the processing unit is configured to determine to stop training of the existing machine learning algorithm, the determination comprising a determination of the sensitivity of the trained machine learning algorithm to at least a portion of the plurality of behavioral data.

In an example, the determination of the sensitivity of the trained machine learning algorithm to at least the portion of the plurality of behavioral data comprises an analysis of a loss function of the trained machine learning algorithm with respect to at least the portion of the plurality of behavioral data.

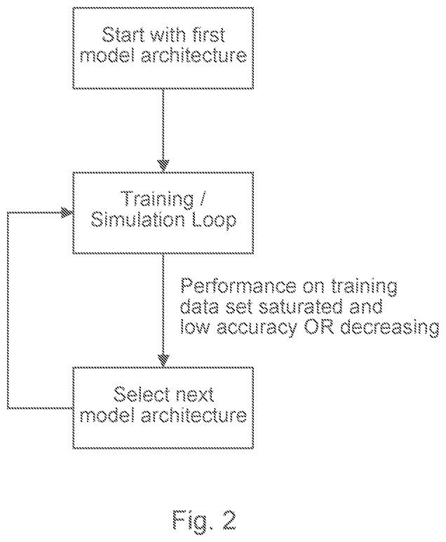

The industrial process training data generation system, industrial process monitoring systems, the method of generating industrial process training data, and the industrial process monitoring methods are now described in further detail with respect to specific detailed embodiments, where reference is again made to FIGS. 1-2.

FIG. 1 shows an overview of the integrated workflow of model training and training data generation using high fidelity simulators.

To begin with there are a number of predefined operator input value trajectories and disturbance trajectories, e.g. a set of step changes on the relevant setpoints of the process or activation or deactivation of actuator failures like valve failures. The operator input value trajectories and disturbance trajectories can be for simplicity be termed together as input value trajectories. Such step change experiments are well known from system identification. With the input value trajectories and the disturbance trajectories, labels can be created along with the simulation data. Data from the introduction of a disturbance in the simulation is labeled as abnormal or failure. In case of system identification tasks, the data after a setpoint change (response) serve as label information for the machine learning process.

These input value trajectories are used to control the process in a number of simulation runs. One simulation run captures the system behavior and response to one input value trajectory. At the end of these simulation runs, the initial training data set has been created.

In the next step, a machine learning algorithm (here algorithm could mean more than one algorithm running together) is trained by being presented the training data changing the parameters of the underlying model (It has been established that the machine learning algorithm can be based on deep learning network, linear regression, random forest, SVM, etc.) based on a loss function. At the end of this step, the first model has been trained. During this step, the training data set can be split into a training data set and a test (hold out) data set. Furthermore, the training data set can be repeatedly split into a training and validation data set (cross validation).

In the next step, the system extracts the sensitivity of the machine learning algorithm(s) towards the entire space of possible inputs to the algorithm(s). One way is to analyze the loss function (a measure of the models prediction error) of the model in both the training set or validation set samples. However, it is known how this can be carried out in other ways.

Based on additional constraints (e.g. min and max values of the setpoints, or thresholds of system trips) the most informative new inputs are generated. When using existing samples in the training or validation data set, the new inputs can be generated creating input value trajectories in the neighborhood of the original data points.

The new setpoint and disturbance trajectories (input value trajectories) are used as inputs for new simulation runs. These runs create new data points. First, the existing model is tested on the new data points. If the performance is good enough (e.g. based on a target accuracy, or target false positives/false negative rates), the process finishes and the created machine learning model can be used online.

If the model is not good enough, the new data points are added to training data set and the machine learning model is retrained in order to improve it.

In a variant of the above process more than a single machine learning model can be trained, but a group of machine learning algorithms or models can be trained. The most informative points are then a mixture of the most informative points across all models. Models that keep producing significantly poorer results (e.g., based on a statistical test) then other models can be excluded from the process.

In another variant of the above sketched process the training data set also contains historical data from an actual plant for the initial training.

FIG. 2 shows an external process to the process sketched in FIG. 1. Here a search process starts from a very simple machine learning model (e.g., a logistic regression or an artificial neural network with few layers). When the model performance saturates on a poor accuracy (or some other performance measure) or even starts decreasing while being presented more informative data, the search process changes to a more complex model—either by a predefined list of machine learning models or by adding additional degree of freedoms to the model architecture, e.g. by adding layers. Also a combination of the two methods is possible—first increase the complexity of a given class of e.g. deep learning networks and then change to a more complex network architecture.

As detailed in the above, a workflow has been developed in which the machine learning model or its performance on individual samples in the training or validation data set are used to determine new simulation inputs, that would result in simulation runs highly informative for the machine learning model. The new data is generated with the simulation system. The already trained algorithm(s) is tested on the new, never seen data. If the performance of the algorithm is sufficient, the process stops. If the performance is not sufficient, the new data is added to training data and the machine learning model is retrained and the process continues.

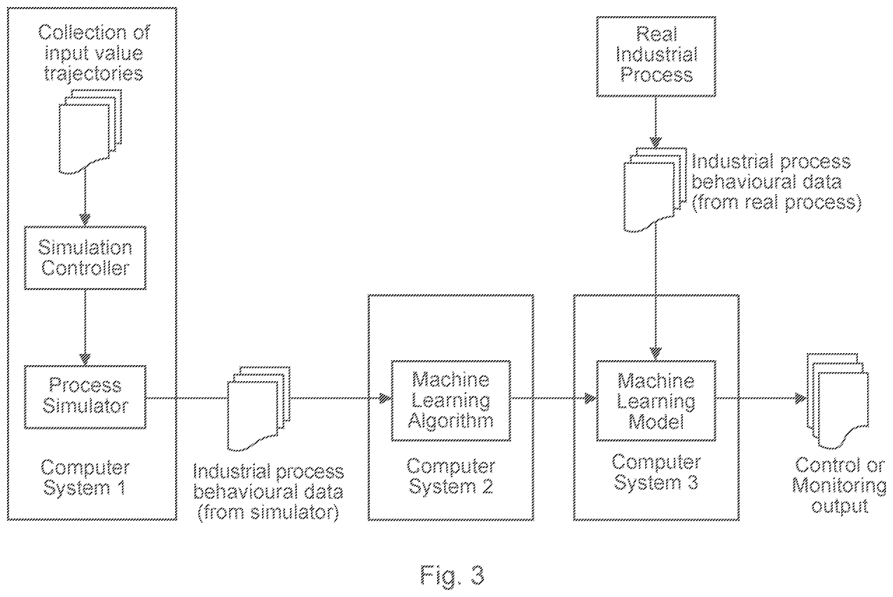

To further explain the industrial process model generation system, industrial process model selection and generation system and associated methods, reference is made to FIGS. 3-5.

FIG. 3 shows a detailed example of an existing simulation workflow. The simulation of the industrial process takes two types of inputs: [1] inputs as the operator of the process would make and [2] inputs that are only possible in the simulation and in reality are outside of the control of an operator, e.g. equipment failures, raw material quality, outside temperature etc.

To generate data to train a machine learning model, trajectories of these inputs need to be defined to control the simulation. The trajectories define for example that “at minute 5, the operator opens a valve” and “at minute 20 the valve starts leaking 50% of the flow.”

The output of the process simulator are all the values usually available in a process control system (setpoints, sensor readings, actuator values like valve positions).

This method is used to train machine learning algorithms, for example, to (1) detect process anomalies, (2) detect device failures, (3) predict the future behavior of the process, and (4) select the best possible next controller output.

The output of the training is a model that can be fed with new and previously unseen data and can perform for example can perform one of the task (1)-(4).

The model is connected to the real industrial process (which produces the same types of data points as the simulator version) and will perform the task and generate the corresponding output.

In this flow, a human would define the input trajectories, review the result of the ML algorithms (the performance of the model) and decide what input value trajectories to use in the next iteration.

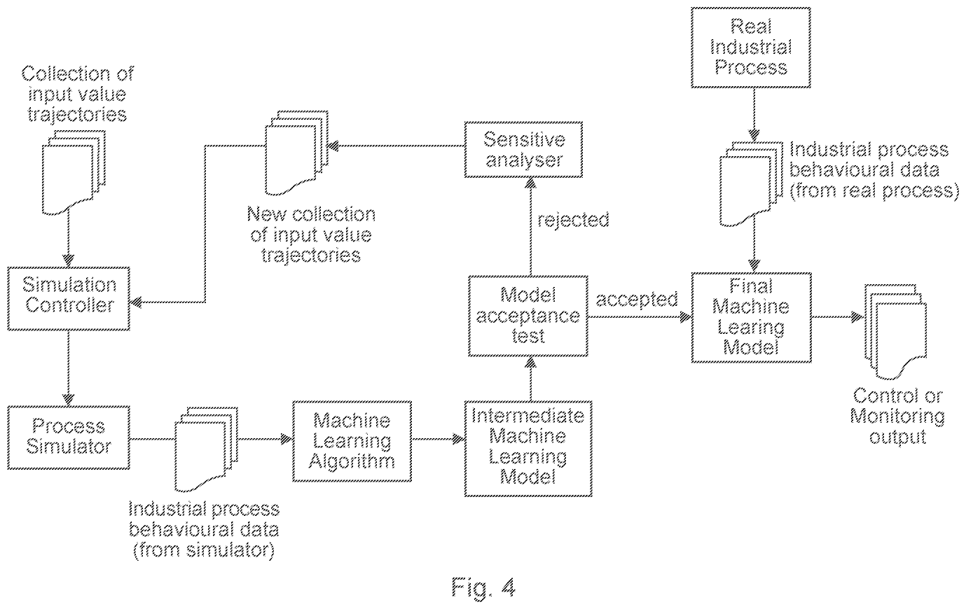

FIG. 4 shows a detailed example of a development described in the present disclosure. The new development includes analyzing the model that is generated by the machine learning algorithms in order to find out, which new data will yield the best improvement of the generated model.

When the model is good enough for usage in the real process, no new data will be generated and the model will be used. In this flow, the system or method test the model, analyzes the model and decides what new input value trajectories are used in the next iteration.

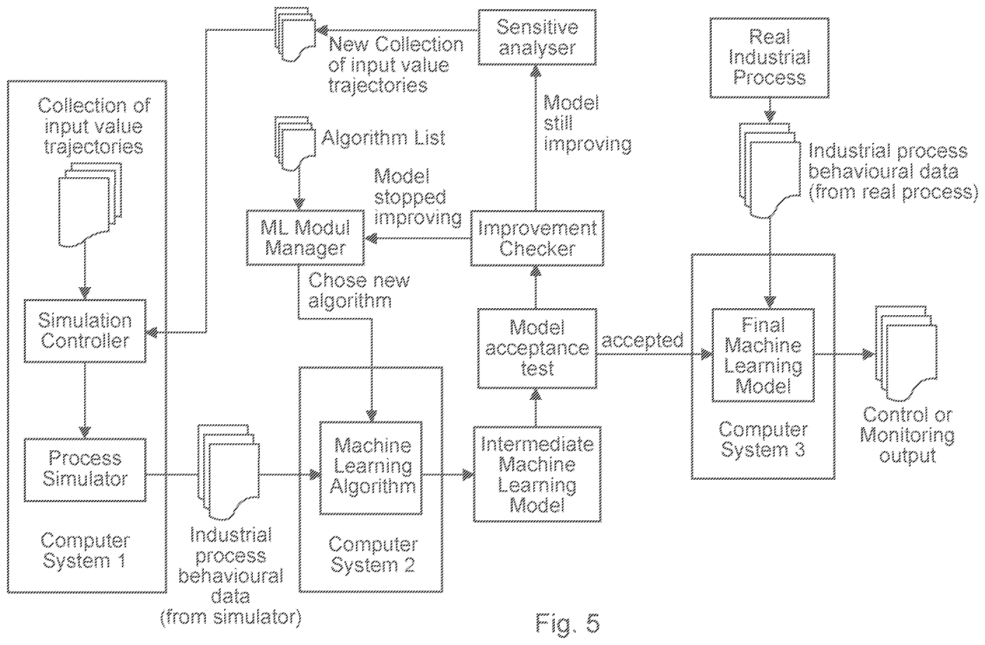

FIG. 5 shows a detailed example of a further development made by the inventors.

The extension relates to the introduction of another loop besides the repeated data generation and training.

After the model acceptance check, the improvement checker tests if the model is still improving by adding new data to the data set. This can be done either by directly analyzing the sensitivity of the model on the input (if the sensitivity is low across all inputs, the model cannot be much further improved) or by simply tracking if the model has seen an improvement above a threshold value in the last n versions. The performance is measured by some performance measure like the F1 Score (for classification) or the RMSE (root mean-squared error) (for regression).

When the model is not improving anymore (and will not improve based on the output of the sensitivity layer) a model manager maintains a list of algorithms, starting from the simplest ML algorithms (e.g. linear regression (regression) or logistic regression (classification) towards more complex algorithms (e.g. Support Vector Machines and Deep Learning Artificial Neural Networks). Each time the ML model stopped improving the next more complex model is chosen and the training starts again—always starting all the training data available at that time.

Complexity for artificial neural networks is determined by the complexity of the architecture, e.g., measured by number of hidden layers and number of nodes in the hidden layer.

In this flow, the system or method still tests the model, analyzes the model and decides what new input value trajectories are used in the next iteration. In addition, the system or method decides if the currently used machine learning algorithms can still be improved and might achieve the required performance or if a more complex algorithm should be used.

Note: One does not use the most complex algorithm at the beginning, because it might “overfit” the training data (basically creates a look-up-table for the training data) and will not be able to generalize towards data outside the training data set.

In FIGS. 3-5, it is shown that different computers, or processing units of such computers, can carry out different functions. This can be the case, but also a single processing unit can carry out all the different functions if required.

Sensitivity Analysis

Regarding analysing the sensitivity of the machine learning algorithm or model, the following are three examples relating to this.

One example of analyzing the sensitivity of the machine learning model is to select the n industrial process behavioral data for which the machine learning model differs most from the actual value (the difference is also called the prediction error). To generate the input value trajectories that will help the model to improve, the n input value trajectories that were used to generate the n industrial process behavioral with largest prediction error are varied, e.g. by randomly changing the initial state of the simulation or changing randomly some of the input values within the input value trajectory.

In another example, another machine learning model algorithm is trained to predict the prediction error of the first machine algorithm using the initial state and other characteristic of the input value trajectory as predictor variables. This machine learning model can be for instance a decision tree, which will return a sequence of decision which input value trajectory values will yield a poor prediction on the current machine learning model. This information can be used to generate new input value trajectories with exactly these content, for instance specific initial states for simulation, specific types of operator inputs (e.g. setpoint changes, manual actuator changes) and parameters of these inputs (e.g. initial setpoint and new setpoint), or failure types.

In another example specific for artificial neural networks, new high-information data points are generated as follows: An optimization algorithm (such as genetic algorithms, a reinforcement learning algorithms, or a Bayesian optimization algorithms) produces input values trajectories that are used to produce behavioral data using the process simulation system. For each behavioral data, the derivative (i.e., the sensitivity) of the neural network prediction (model response) with respect to the model parameters can be evaluated without the need to undergo an entire training and validation cycle. This means that this gradient information can be evaluated for a large number of candidate points in a short amount of time. The resulting points are “high-information” points in the following sense: During subsequent training, a gradient-descent type algorithm will take large steps towards a better solution in case the prediction error is high, i.e., if the model can be improved. During subsequent training, a gradient-descent type algorithm will stay in the vicinity of its current solution in case the prediction error is low, i.e., if the model generalizes well to the newly found input trajectories.

Therefore, input trajectories that have maximized sensitivity of the model response will either cause the model to improve or validate the current model. In special cases, when the input to artificial neural network (the predictor variables) only contain information that is part of the input value trajectory and the output of the process simulation (the process behavioral data) is part of the output (predicted value) the step of process simulation can be avoided and a large number of candidate input value trajectory can be directly evaluated using the derivative of the neural network prediction (model response) with respect to the model parameters. In this case, the time to evaluate candidate input trajectories is even shorter.

While the invention has been illustrated and described in detail in the drawings and foregoing description, such illustration and description are to be considered illustrative or exemplary and not restrictive. The invention is not limited to the disclosed embodiments. Other variations to the disclosed embodiments can be understood and effected by those skilled in the art in practicing a claimed invention, from a study of the drawings, the disclosure, and the dependent claims.

Thus, a set of industrial process behavioral data is produced by the simulator based on input value trajectories that can be real values or simulated, and a machine learning algorithm is trained on subsets of this data, with the system deciding which subsets of the data to actually use in that training.

The machine learning algorithm can be trained on “real” industrial process behavioral data in addition to that generated by the simulator, in that the plurality of industrial process behavioral data can then comprise that generated by the simulator and the “real” data. However, all of the plurality of industrial process behavioral data can be that as generated by the simulator.

In this way, as new input trajectories are provided, that are real input data or simulated input data, associated behavioral data generated from a simulator can be used to train a machine learning model or not to train the machine learning model of the industrial process. This continues stepwise as behavioral data is generated, where the machine learning algorithm is continually trained with appropriate data but not trained with data that is not appropriate.

The operational input value trajectories are any inputs a plant operator would make to the production process. These are for example setpoints (target values for automation/control loop(s)), parameters for actuators (for example a percentage opening or closing of a valve) and digital inputs (pump on/off).

In addition to inputs an operator would make (operational input value trajectories), there are also inputs to configure and control the simulation. Examples are the initial plant state at the beginning of the simulation, raw-material composition/quality, simulation of failures at certain types, for example, valve failures such as leakage, sticking, and the like, rotating equipment failures (pumps, compressors) etc. These are termed simulation input value trajectories.

Thus, input value trajectories are inputs that control (feed-forward) the simulation process, and the simulator can produce industrial process behavioral data that comprises for example one or more of: process data (e.g. simulated temperature, pressure, level, flow values), actuator data (simulated valve positions, heat exchanger inflow, motor currents etc.), setpoints (e.g. target values for PID ((proportional integral derivative) controller).

It is to be noted that “a processor” and “the processor” does not mean that system must use only one processor. For example a processor can implement the simulator to produce data and a second processor implement the machine learning algorithm.

In an example, the plurality of behavioral data comprises one or more of: process data; temperature data; pressure data; flow data; level data; voltage data; current data; power data; actuator data; valve data; sensor data; controller data.

Thus, input value trajectories are inputs that control (feed-forward) the simulation process, and the simulator can produce industrial process behavioral data that comprises for example one or more of: initial simulation state (e.g. simulated temperature, pressure, level, flow values), actuator data (simulated valve positions, heat exchanger inflow, motor currents etc.), setpoints (e.g. target values for PID ((proportional integral derivative) controller).

In an example, the modelled result comprises a control or monitoring output of the industrial process.

Thus, the machine learning algorithm is trained to produce a machine learning model that for example realizes a task control or monitors the actual industrial process that is simulated.

In an example, the processing unit is configured to select the at least some of the plurality of input value trajectories.

Thus, the system can select or decide on which input value trajectories are to be provided to the simulator to generate new behavioral data that could be used for training, which optimizes computational efficiency as the simulator may not need to be invoked.

In an example, the selection of the at least some of the plurality of input value trajectories comprises utilization of a determined sensitivity of the trained machine learning algorithm to at least a portion of the plurality of behavioral data.

In an example, the determination to train or not to train the machine learning algorithm using the first behavioral data, comprises a determination of a sensitivity of the trained machine learning algorithm to at least a portion of the plurality of behavioral data.

In an example, the determination to train or not to train the machine learning algorithm using the second behavioral data, comprises a determination of the sensitivity of the trained machine learning algorithm to at least a portion of the plurality of behavioral data.

In an example, the determination to further train or not to further train the machine learning algorithm using the second behavioral data, comprises a determination of the sensitivity of the trained machine learning algorithm to at least a portion of the plurality of behavioral data.

In an example, the determination of the sensitivity of the trained machine learning algorithm to at least the portion of the plurality of behavioral data comprises an analysis of a loss function of the trained machine learning algorithm with respect to at least the portion of the plurality of behavioral data.

In an example, the processing unit is configured to determine to stop training of the machine learning algorithm, the determination comprising a determination of a sensitivity of the trained machine learning algorithm to at least a portion of the plurality of behavioral data.

Thus, the machine learning algorithm (model) is analyzed to identify which operational input trajectories and simulation input value trajectories should be used for generating new behavioral data for training of the machine learning algorithm in order so that the newly generated simulated data will significantly change the machine learning model “a lot” as the machine learning algorithms is trained (additionally) on the new data. And, when the machine learning algorithm is not being significantly changed, the training can be stopped and a final trained machine learning algorithm can be provided to model the process.

In a second aspect, there is provided an industrial process model selection and generation system, comprising:

an input unit; and

a processing unit.

The input unit is configured to receive a plurality of input value trajectories comprising operational input value trajectories and simulation input value trajectories. The processing unit is configured to implement a simulator of the industrial process. The processing unit is configured to generate a plurality of industrial process behavioral data. Industrial process behavioral data is generated for at least some of the plurality of input value trajectories, and the generation of the industrial process behavioral data for the at least some of the plurality of input value trajectories comprises utilization of the simulator. The processing unit is configured to implement a plurality of machine learning algorithms that model the industrial process. The processing unit is configured to process a first behavioral data of the plurality of behavioral data with a first machine learning algorithm of the plurality of machine learning algorithms to determine a first machine learning algorithm first modelled result. The processing unit is configured to determine to train the first machine learning algorithm using the first behavioral data or implement a second machine learning algorithm of the plurality of machine learning algorithms, the determination comprising a comparison of the first machine learning algorithm first modelled result with a performance condition.

In an example, the processing unit is configured to process a second behavioral data of the plurality of behavioral data with the first machine learning algorithm to determine a first machine learning algorithm second modelled result. The processing unit is configured to determine to train the first machine learning algorithm using the second behavioral data or implement the second machine learning algorithm, the determination comprising a comparison of the first machine learning algorithm second modelled result with the performance condition.

In an example, the processing unit is configured to process the first behavioral data with the second machine learning algorithm to determine a second machine learning algorithm first modelled result. The processing unit is configured to determine to train the second machine learning algorithm using the first behavioral data or implement a third machine learning algorithm of the plurality of machine learning algorithms, the determination comprising a comparison of the second machine learning algorithm first modelled result with the performance condition.

In this way, as new input trajectories are provided, that are real input data or simulated input data, associated behavioral data generated from a simulator can be used to train a machine learning model or select and train a different machine learning model of the industrial process. This continues stepwise as behavioral data is generated, where the machine learning algorithm is continually trained with appropriate data or a different machine learning algorithm is selected and trained with appropriate data.

In an example, the processing unit is configured to select the at least some of the plurality of input value trajectories.

Thus, the system can select or decide on which input value trajectories are to be provided to the simulator to generate new behavioral data that could be used for training, which optimizes computational efficiency as the simulator may not need to be invoked.

In an example, the selection of the at least some of the plurality of input value trajectories comprises utilization of a determined sensitivity of the trained machine learning algorithm to at least a portion of the plurality of behavioral data.

In an example, the determination to train the existing machine learning algorithm using behavioral data or implement a new machine learning algorithm, comprises a determination of a sensitivity of the existing trained machine learning algorithm to at least a portion of the plurality of behavioral data.

In an example, the processing unit is configured to determine to stop training of the existing machine learning algorithm, the determination comprising a determination of the sensitivity of the trained machine learning algorithm to at least a portion of the plurality of behavioral data.

In an example, the determination of the sensitivity of the trained machine learning algorithm to at least the portion of the plurality of behavioral data comprises an analysis of a loss function of the trained machine learning algorithm with respect to at least the portion of the plurality of behavioral data.

Thus, the machine learning algorithm (model) is analyzed to identify which operational input trajectories and simulation input value trajectories should be used for generating new behavioral data for training of the machine learning algorithm in order so that the newly generated simulated data will significantly change the machine learning model “a lot” as the machine learning algorithms is trained (additionally) on the new data. And, when the machine learning algorithm is not performing as required a more sophisticated machine learning algorithm can be implemented and when that machine learning algorithm is not being significantly changed, the training can be stopped and a final trained machine learning algorithm can be provided to model the process.

In an example, the first machine learning algorithm is a simplest machine learning algorithm of the plurality of machine learning algorithms.

In an example, the second machine learning algorithm is a second most simple machine learning algorithm of the plurality of machine learning algorithms.

In an example, the third machine learning algorithm is a third most simplest machine learning algorithm of the plurality of machine learning algorithms.

In a third aspect, there is provided an industrial process model generation method, comprising:
receiving a plurality of input value trajectories comprising operational input value trajectories and simulation input value trajectories relating to an industrial process;
implementing by a processing unit a simulator of the industrial process;
generating by the processing unit a plurality of industrial process behavioral data, wherein the industrial process behavioral data is generated for at least some of the plurality of input value trajectories, and wherein the generation of the industrial process behavioral data for the at least some of the plurality of input value trajectories comprises utilization of the simulator;
implementing by the processing unit a machine learning algorithm that models the industrial process, wherein the processing unit is configured to train the machine learning algorithm;
processing by the processing unit a first behavioral data of the plurality of behavioral data with the machine learning algorithm to determine a first modelled result;
determining by the processing unit to train or not to train the machine learning algorithm using the first behavioral data, the determination comprising a comparison of the first modelled result with a performance condition;
processing by the processing unit a second behavioral data of the plurality of behavioral data with the machine learning algorithm to determine a second modelled result;
determining by the processing unit to train or not to train the machine learning algorithm using the second behavioral data or to further train or not to further train the machine learning algorithm using the second behavioral data, the determination comprising a comparison of the second modelled result with the performance condition.

In an example, the method comprises selecting by the processing unit the at least some of the plurality of input value trajectories.

In an example, the selecting of the at least some of the plurality of input value trajectories comprises utilizing a determined sensitivity of the trained machine learning algorithm to at least a portion of the plurality of behavioral data.

In an example, the determining to train or not to train the machine learning algorithm using the first behavioral data, comprises determining a sensitivity of the trained machine learning algorithm to at least a portion of the plurality of behavioral data.

In an example, the determining to train or not to train the machine learning algorithm using the second behavioral data, comprises determining the sensitivity of the trained machine learning algorithm to at least a portion of the plurality of behavioral data.

In an example, the determining to further train or not to further train the machine learning algorithm using the second behavioral data, comprises determining the sensitivity of the trained machine learning algorithm to at least a portion of the plurality of behavioral data.

In an example, the determining the sensitivity of the trained machine learning algorithm to at least the portion of the plurality of behavioral data comprises analyzing a loss function of the trained machine learning algorithm with respect to at least the portion of the plurality of behavioral data.

In an example, the method comprises determining by the processing unit to stop training the machine learning algorithm, the determining comprising determining a sensitivity of the trained machine learning algorithm to at least a portion of the plurality of behavioral data.

In a fourth aspect, there is provided an industrial process model selection and generation method, comprising:
receiving a plurality of input value trajectories comprising operational input value trajectories and simulation input value trajectories relating to an industrial process;
implementing by a processing unit a simulator of the industrial process;
generating by the processing unit a plurality of industrial process behavioral data, wherein the industrial process behavioral data is generated for at least some of the plurality of input value trajectories, and wherein the generation of the industrial process behavioral data for the at least some of the plurality of input value trajectories comprises utilization of the simulator;
implementing by the processing unit a first machine learning algorithm of a plurality of machine learning algorithms that model the industrial process;
processing by the processing unit a first behavioral data of the plurality of behavioral data with the first machine learning algorithm of the plurality of machine learning algorithms to determine a first machine learning algorithm first modelled result; and
determining by the processing unit to train the first machine learning algorithm using the first behavioral data or implement a second machine learning algorithm of the plurality of machine learning algorithms, the determination comprising a comparison of the first machine learning algorithm first modelled result with a performance condition.

In an example, the method comprises processing by the processing unit a second behavioral data of the plurality of behavioral data with the first machine learning algorithm to determine a first machine learning algorithm second modelled result; and determining by the processing unit to train the first machine learning algorithm using the second behavioral data or implement the second machine learning algorithm, the determination comprising a comparison of the first machine learning algorithm second modelled result with the performance condition.

In an example, the method comprises processing with the processing unit the first behavioral data with the second machine learning algorithm to determine a second machine learning algorithm first modelled result; and determining by the processing unit to train the second machine learning algorithm using the first behavioral data or implement a third machine learning algorithm of the plurality of machine learning algorithms, the determination comprising a comparison of the second machine learning algorithm first modelled result with the performance condition.

In an example, the method comprises selecting by the processing unit the at least some of the plurality of input value trajectories.

In an example, the selecting of the at least some of the plurality of input value trajectories comprises utilizing a determined sensitivity of the trained machine learning algorithm to at least a portion of the plurality of behavioral data.

In an example, determining to train the existing machine learning algorithm using behavioral data or implement a new machine learning algorithm, comprises a determination of a sensitivity of the existing trained machine learning algorithm to at least a portion of the plurality of behavioral data.

In an example, the processing unit is configured to determine to stop training of the existing machine learning algorithm, the determination comprising a determination of the sensitivity of the trained machine learning algorithm to at least a portion of the plurality of behavioral data.

In an example, the determination of the sensitivity of the trained machine learning algorithm to at least the portion of the plurality of behavioral data comprises an analysis of a loss function of the trained machine learning algorithm with respect to at least the portion of the plurality of behavioral data.

Thus, the machine learning algorithm (model) is analyzed to identify which operational input trajectories and simulation input value trajectories should be used for generating new behavioral data for training of the machine learning algorithm in order so that the newly generated simulated data will significantly change the machine learning model “a lot” as the machine learning algorithms is trained (additionally) on the new data. And, when the machine learning algorithm is not performing as required a more sophisticated machine learning algorithm can be implemented and when that machine learning algorithm is not being significantly changed, the training can be stopped and a final trained machine learning algorithm can be provided to model the process.

The above aspects and examples will become apparent from and be elucidated with reference to the embodiments described hereinafter.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. An industrial process model generation system, comprising:
an input unit; and
a processing unit;
wherein, the input unit is configured to receive a plurality of input value trajectories comprising operational input value trajectories and simulation input value trajectories relating to an industrial process;
wherein, the processing unit is configured to implement a simulator of the industrial process;
wherein, the processing unit is configured to generate a plurality of industrial process behavioral data, wherein industrial process behavioral data is generated for at least some of the plurality of input value trajectories, and wherein the generation of the industrial process behavioral data for the at least some of the plurality of input value trajectories comprises utilization of the simulator;
wherein, the processing unit is configured to implement a machine learning algorithm that models the industrial process;
wherein, the processing unit is configured to train the machine learning algorithm;
wherein, the processing unit is configured to process a first behavioral data of the plurality of behavioral data with the machine learning algorithm to determine a first modelled result;
wherein, the processing unit is configured to determine to train or not to train the machine learning algorithm using the first behavioral data, the determination comprising a comparison of the first modelled result with a performance condition;
wherein, the processing unit is configured to process a second behavioral data of the plurality of behavioral data with the machine learning algorithm to determine a second modelled result; and
wherein, the processing unit is configured to determine to train or not to train the machine learning algorithm using the second behavioral data or to further train or not to further train the machine learning algorithm using the second behavioral data, the determination comprising a comparison of the second modelled result with the performance condition.

2. The system according to claim 1, wherein the plurality of input value trajectories comprises one or more of: process data; temperature data; pressure data; flow data; level data; voltage data; current data; power data; actuator data; valve data; sensor data; and controller data.

3. The system according to claim 1, wherein the determination to train or not to train the machine learning algorithm using the first behavioral data comprises a determination of a sensitivity of the trained machine learning algorithm to at least a portion of the plurality of behavioral data.

4. The system according to claim 1, wherein the determination to train or not to train the machine learning algorithm using the second behavioral data, comprises a determination of the sensitivity of the trained machine learning algorithm to at least a portion of the plurality of behavioral data.

5. The system according to claim 1, wherein the determination to further train or not to further train the machine learning algorithm using the second behavioral data, comprises a determination of the sensitivity of the trained machine learning algorithm to at least a portion of the plurality of behavioral data.

6. The system according to claim 4, wherein the determination of the sensitivity of the trained machine learning algorithm to at least a portion of the plurality of behavioral data comprises an analysis of a loss function of the trained machine learning algorithm with respect to at least the portion of the plurality of behavioral data.

7. The system according to claim 1, wherein the processing unit is configured to determine to stop training of the machine learning algorithm, the determination comprising a determination of a sensitivity of the trained machine learning algorithm to at least a portion of the plurality of behavioral data.

8. The system according to claim 1, wherein the processing unit is configured to select the at least some of the plurality of input value trajectories.

9. An industrial process model selection and generation system, comprising:
an input unit; and
a processing unit;
wherein, the input unit is configured to receive a plurality of input value trajectories comprising operational input value trajectories and simulation input value trajectories;
wherein, the processing unit is configured to implement a simulator of the industrial process;
wherein, the processing unit is configured to generate a plurality of industrial process behavioral data, wherein the industrial process behavioral data is generated for at least some of the plurality of input value trajectories, and wherein the generation of the industrial process behavioral data for the at least some of the plurality of input value trajectories comprises utilization of the simulator;
wherein, the processing unit is configured to implement a plurality of machine learning algorithm that model the industrial process;
wherein, the processing unit is configured to process a first behavioral data of the plurality of behavioral data with a first machine learning algorithm of the plurality of machine learning algorithms to determine a first machine learning algorithm first modelled result; and
wherein, the processing unit is configured to determine to train the first machine learning algorithm using the first behavioral data or implement a second machine learning algorithm of the plurality of machine learning algorithms, and wherein the determination comprises a comparison of the first machine learning algorithm first modelled result with a performance condition.

10. The system according to claim 9, wherein the processing unit is configured to process a second behavioral data of the plurality of behavioral data with the first machine learning algorithm to determine a first machine learning algorithm second modelled result; and wherein the processing unit is configured to determine to train the first machine learning algorithm using the second behavioral data or implement the second machine learning algorithm, wherein the determination comprising a comparison of the first machine learning algorithm second modelled result with the performance condition.

11. The system according to claim 9, wherein the processing unit is configured to process the first behavioral data with the second machine learning algorithm to determine a second machine learning algorithm first modelled result; and wherein the processing unit is configured to determine to train the second machine learning algorithm using the first behavioral data or implement a third machine learning algorithm of the plurality of machine learning algorithms, wherein the determination comprises a comparison of the second machine learning algorithm first modelled result with the performance condition.

12. The system according to claim 9, wherein the determination to train the existing machine learning algorithm using behavioral data or implement a new machine learning algorithm comprises a determination of a sensitivity of the existing machine learning algorithm to at least a portion of the plurality of behavioral data.

13. The system according to claim 9, wherein the processing unit is configured to determine to stop training of the existing machine learning algorithm, wherein the determination comprises a determination of a sensitivity of the trained machine learning algorithm to at least a portion of the plurality of behavioral data.

14. The system according to claim 12, wherein the determination of the sensitivity of the trained machine learning algorithm to at least the portion of the plurality of behavioral data comprises an analysis of a loss function of the trained machine learning algorithm with respect to at least the portion of the plurality of behavioral data.

15. The system according to claim 9, wherein the processing unit is configured to select the at least some of the plurality of input value trajectories.

16. An industrial process model generation method, comprising:
receiving a plurality of input value trajectories comprising operational input value trajectories and simulation input value trajectories relating to an industrial process;
implementing by a processing unit a simulator of the industrial process;
generating by the processing unit a plurality of industrial process behavioral data, wherein the industrial process behavioral data is generated for at least some of the plurality of input value trajectories, and wherein the generation of the industrial process behavioral data for the at least some of the plurality of input value trajectories comprises utilization of the simulator;
implementing by the processing unit a machine learning algorithm that models the industrial process, wherein the processing unit is configured to train the machine learning algorithm;
processing by the processing unit a first behavioral data of the plurality of behavioral data with the machine learning algorithm to determine a first modelled result;
determining by the processing unit to train or not to train the machine learning algorithm using the first behavioral data, the determination comprising a comparison of the first modelled result with a performance condition;
processing by the processing unit a second behavioral data of the plurality of behavioral data with the machine learning algorithm to determine a second modelled result; and
determining by the processing unit to train or not to train the machine learning algorithm using the second behavioral data or to further train or not to further train the machine learning algorithm using the second behavioral data, the determination comprising a comparison of the second modelled result with the performance condition.

17. An industrial process model selection and generation method, comprising:
receiving a plurality of input value trajectories comprising operational input value trajectories and simulation input value trajectories relating to an industrial process;
implementing by a processing unit a simulator of the industrial process;
generating by the processing unit a plurality of industrial process behavioral data, wherein the industrial process behavioral data is generated for at least some of the plurality of input value trajectories, and wherein the generation of the industrial process behavioral data for the at least some of the plurality of input value trajectories comprises utilization of the simulator;
implementing by the processing unit a first machine learning algorithm of a plurality of machine learning algorithms that model the industrial process;
processing by the processing unit a first behavioral data of the plurality of behavioral data with the first machine learning algorithm of the plurality of machine learning algorithms to determine a first machine learning algorithm first modelled result; and
determining by the processing unit to train the first machine learning algorithm using the first behavioral data or implement a second machine learning algorithm of the plurality of machine learning algorithms, the determination comprising a comparison of the first machine learning algorithm first modelled result with a performance condition.
